(19) United States
(12) Patent Application Publication
(10) Pub. No.: US 2013/0023104 A1
(43) Pub. Date: Jan. 24, 2013

(54) METHOD FOR MANUFACTURING SEMICONDUCTOR DEVICE

(71) Applicant: Tatsunori ISOGAI, Kanagawa-ken (JP)

(72) Inventor: Tatsunori ISOGAI, Kanagawa-ken (JP)

(21) Appl. No.: 13/538,100

(22) Filed: Jun. 29, 2012

(30) Foreign Application Priority Data
Jul. 19, 2011 (JP) 2011-158173

(51) Int. Cl. H01L 21/265; H01L 21/336

(52) U.S. Cl. 438/306; 438/513; 257/E21.334; 257/E21.409

(57) ABSTRACT

According to an embodiment, a method for manufacturing a semiconductor device includes a step of forming an impurity layer on a semiconductor layer, the impurity layer including an impurity element to be doped to the semiconductor layer, and a step of applying a first gas in a plasma state including a first noble gas atom and a second gas in a plasma state including a second noble gas atom or hydrogen (H) toward the impurity layer, the second noble gas atom having a smaller atomic mass than the first noble gas atom.

### CROSS-REFERENCE TO RELATED APPLICATIONS

This application is based upon and claims the benefit of priority from Japanese Patent Application No. 2011-158173, filed on Jul. 19, 2011; the entire contents of which are incorporated herein by reference.

### FIELD

Embodiments are related generally to a method for manufacturing a semiconductor device.

### BACKGROUND

In the process for manufacturing MOS transistors, the ion implantation using ion beam is typically performed in a plurality of steps. In the ion implantation process, desired impurity ions (dopant ions) selected by a mass spectrometer are accelerated and implanted into a semiconductor layer. In this kind of ion implantation, transport efficiency of the ion beam decreases, when the impurity ions are implanted at a low acceleration condition. This may decrease the productivity of the MOS transistors.

Furthermore, recent semiconductor devices have higher performance and higher integration density. In this context, the so-called three-dimensional process has been investigated for constructing a three-dimensional device. But the ion beam implantation may be unsuitable for the three-dimensional process, since the implant efficiency becomes lower in the wall portion than in the planar portion.

Therefore, the method called plasma doping has been drawing attention, because it is advantageous in the low acceleration condition and useful for the three-dimensional process. In this method, the impurity gas diluted with a noble gas that has a relatively large atomic mass, such as Ar, Kr, and Xe, is excited into the plasma state, wherein the impurity ions generated in the plasma are implanted into the semiconductor layer. At the same time, the noble gas elements are injected into the semiconductor layer, and form an amorphous layer. The impurity ions included in the amorphous layer may be activated at relatively low temperature, while a solid state epitaxial growth occurs in the amorphous layer.

However, the noble gas element having a larger atomic mass is injected less deeply into the semiconductor layer, when having the same kinetic energy. That is, as the atomic mass of the noble gas becomes larger, the thickness of the amorphous layer becomes thinner. Thus, a large amount of impurity ions may be implanted at a position deeper than the depth of the amorphous layer. In such a case, it is difficult to activate the impurity ions implanted below the amorphous layer using the low temperature annealing. On the other hand, when the annealing temperature is too high, the impurity ions are excessively diffused in the semiconductor layer. This makes it difficult to obtain a desired impurity concentration profile.

### BRIEF DESCRIPTION OF THE DRAWINGS

FIGS. 1A to 3C are schematic cross-sectional views for describing a process for manufacturing a semiconductor device according to a first embodiment;

FIGS. 4A to 4C are schematic cross-sectional views for describing a process for manufacturing a semiconductor device according to a reference example;

FIGS. 5A to 11B are schematic sectional views illustrating a manufacturing process for a semiconductor device according to a second embodiment; and

FIGS. 12A to 13B are schematic sectional views for describing the process for manufacturing the semiconductor device according to the second embodiment.

### DETAILED DESCRIPTION

According to an embodiment, a method for manufacturing a semiconductor device includes a step of forming an impurity layer on a semiconductor layer, the impurity layer including an impurity element to be doped to the semiconductor layer, and a step of applying a first gas in a plasma state including a first noble gas atom and a second gas in a plasma state including a second noble gas atom or hydrogen (H) toward the impurity layer, the second noble gas atom having a smaller atomic mass than the first noble gas atom.

Embodiments will now be described with reference to the drawings. In the following description, like portions are labeled with like reference numerals, and the description of the portions once described is omitted appropriately.

### First Embodiment

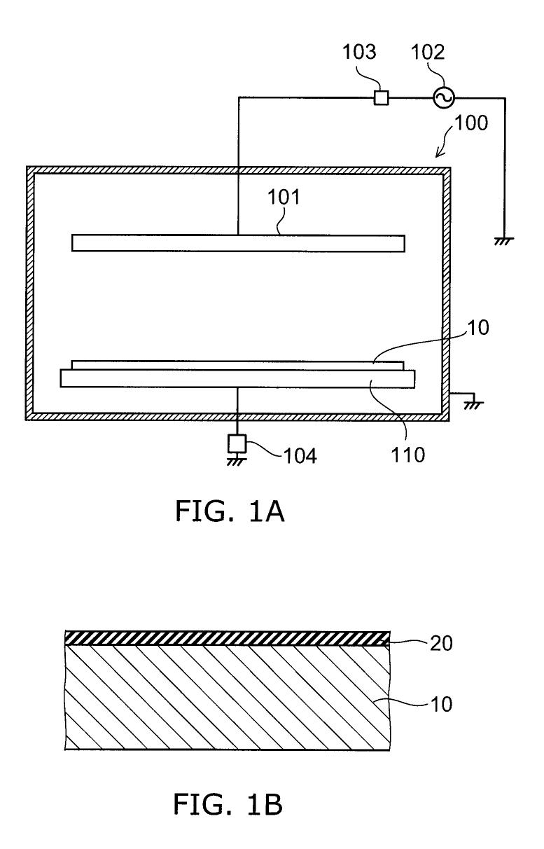

FIGS. 1A and 1B are schematic sectional views for describing a process for manufacturing a semiconductor device according to a first embodiment. FIG. 1A is a schematic sectional view of a vacuum processing apparatus and a semiconductor layer. FIG. 1B is a schematic sectional view of the semiconductor layer and an impurity layer. The semiconductor layer may be provided on a substrate, or may be the substrate itself.

First, as shown in FIG. 1A, a semiconductor layer 10 is placed on a stage 110 in a vacuum processing apparatus 100.

The vacuum processing apparatus 100 includes a radio frequency power supply 102 for supplying electrical power to a cathode electrode 101, and a low pass filter 103 connected between the radio frequency power supply 102 and the cathode electrode 101. The vacuum processing apparatus 100 includes a bias power supply 104 for applying a bias potential to the semiconductor layer 10. In addition, the vacuum processing apparatus 100 is provided with a gas evacuation system, a gas introduction line, and a gas flow rate control system (not shown). The cathode electrode 101 shown in FIG. 1A is shaped like a flat plate. However, the cathode electrode 101 may be shaped like a coil, or may be a shower nozzle serving as a gas introduction line.

The semiconductor layer 10 is e.g. a silicon (Si) monocrystalline substrate with the surface orientation of the major surface in a (100) plane. Instead of the silicon monocrystalline substrate, the semiconductor layer 10 may be a monocrystalline substrate made of germanium (Ge), silicon carbide (SiC), or gallium arsenide (GaAs), for example. The semiconductor layer may also be a silicon germanium (SiGe) layer provided on the silicon substrate or an SOI (silicon on insulator).

Next, as shown in FIG. 1B, an impurity layer 20 is formed on the semiconductor layer 10. The impurity layer 20 includes an impurity element to be doped into the semiconductor layer 10. FIG. 1B shows the vicinity of the surface of the semiconductor layer 10.

The impurity layer 20 is formed by e.g. plasma enhanced CVD (chemical vapor deposition). For instance, in the first embodiment, for example, the impurity layer 20 includes boron (B), which is a p-type impurity. In this case, the source gas used in plasma enhanced CVD is e.g. diborane (B₂H₆) diluted with helium (He). While forming the impurity layer, for instance, the flow rate of helium (He) is 250 sccm, and the flow rate of diborane (B₂H₆) is 10 sccm. Besides boron (B), the impurity layer 20 may include e.g. phosphorus (P) or arsenic (As).

The atmosphere pressure of the mixed gas is maintained to be e.g. 0.5 Pa while forming the impurity layer.

The cathode electrode 101 in the vacuum processing apparatus 100 is supplied with an electrical power of 2000-4000 W. Thus, the mixed gas is subjected to electrical discharge, and plasma is generated in the vacuum processing apparatus 100. The electrical power is a radio frequency electrical power at a frequency of 13.56 MHz.

The thickness of the impurity layer 20 is appropriately adjusted in accordance with the target dose amount. For instance, as the thickness of the impurity layer 20 is set thicker, the dose amount into the semiconductor layer 10 becomes larger. In forming the impurity layer 20, a bias voltage of several ten W may be applied to the semiconductor layer 10. While forming the impurity layer 20, applying a bias voltage to the semiconductor layer 10 makes the impurity layer 20 denser. As the density of the impurity layer 20 becomes higher, the variation of impurity concentration per unit area becomes smaller in the semiconductor layer 10 after the plasma doping process described later. Subsequently, the semiconductor layer 10 is introduced into a plasma doping apparatus.

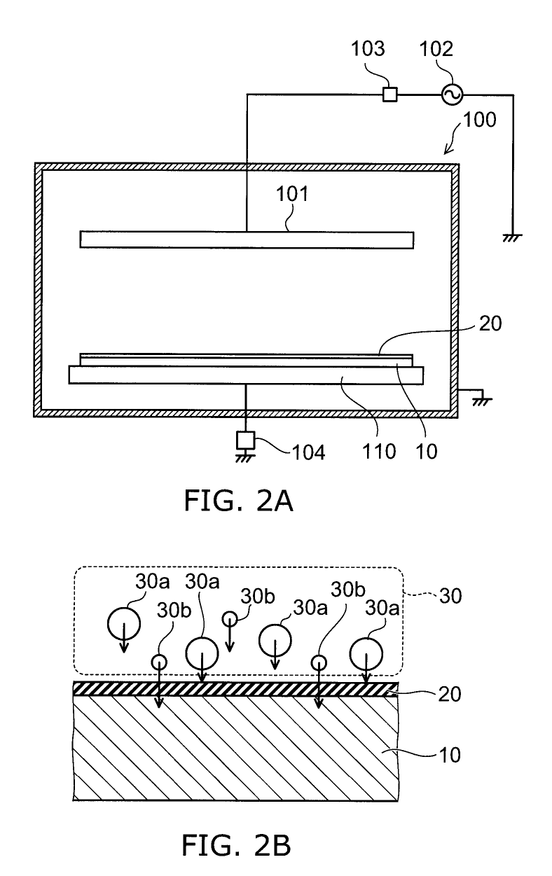

FIGS. 2A and 2B are schematic sectional views for describing the process for manufacturing a semiconductor device according to the first embodiment. FIG. 2A is a schematic sectional view of the vacuum processing apparatus and the semiconductor layer. FIG. 2B is a schematic cross-sectional view illustrating the semiconductor layer in the plasma doping process.

FIG. 2A shows the state in which the semiconductor layer 10 with the impurity layer 20 formed thereon is placed on the stage 110 in the vacuum processing apparatus 100. Subsequently, the gas species introduced into the vacuum processing apparatus 100 is switched.

Next, as shown in FIG. 2B, plasma processing is performed on the semiconductor layer 10 covered with the impurity layer 20. FIG. 2B shows the vicinity of the surface of the semiconductor layer 10.

As shown in FIG. 2B, a mixed gas 30 including a first gas 30a and a second gas 30b is subjected to electrical discharge and turned into a plasma state. In this case, the first gas 30a in a non-plasma state and the second gas 30b in a non-plasma state may be mixed, and then this mixed gas may be subjected to electrical discharge to form a mixed gas 30 in a plasma state. Alternatively, the first gas 30a and the second gas 30b may be independently turned into plasma, and the first gas 30a in the plasma state and the second gas 30b in the plasma state may be mixed in the vacuum processing apparatus 100. That is, the gas in a plasma state including the first gas 30a and the second gas 30b is formed in the vacuum processing apparatus 100.

In the embodiment, the former mixed gas 30 in the plasma state is illustrated. The first gas 30a includes noble gas atoms (first noble gas atoms). The second gas 30b includes different noble gas atoms (second noble gas atoms) having a smaller atomic mass than the first noble gas atoms, or hydrogen (H). The first gas in the plasma state including the first noble gas atoms, and the second gas in the plasma state including the second noble gas atoms having a smaller atomic mass than the first noble gas atoms or hydrogen (H) are applied toward the impurity layer 20.

In applying the first and second gases to the impurity layer 20, a negative potential relative to the plasma potential of the first and second gases in the plasma state may be applied to the semiconductor layer 10. For instance, in applying the mixed gas 30 in the plasma state (hereinafter also referred to as plasma gas) to the impurity layer 20, a negative potential relative to the plasma potential of the plasma gas may be applied to the semiconductor layer 10 by using the bias power supply 104. As the absolute value of the negative potential applied to the semiconductor layer 10 becomes larger, the acceleration energy of cations in the plasma gas becomes higher. The absolute value of the negative potential is e.g. in the range from 100 V to several hundred Volt.

The first noble gas atom included in the first gas 30a is e.g. one selected from the group consisting of helium (He), neon (Ne), argon (Ar), krypton (Kr), and xenon (Xe).

The second noble gas atom included in the second gas 30b has a smaller atomic mass than the noble gas included in the first gas. The second noble gas atom is at least one selected from the group consisting of helium (He), neon (Ne), argon (Ar), and krypton (Kr). For instance, in the case where the first gas is argon (Ar), the second gas may be helium (He), or a mixed gas of hydrogen (H) and helium (He).

A specific example of the combination of first gas 30a/second gas 30b can be one of neon (Ne)/helium (He), argon (Ar)/helium (He), argon (Ar)/neon (Ne), krypton (Kr)/helium (He), krypton (Kr)/neon (Ne), krypton (Kr)/argon (Ar), xenon (Xe)/helium (He), xenon (Xe)/neon (Ne), xenon (Xe)/argon (Ar), and xenon (Xe)/krypton (Kr).

For instance, consider the case where the first gas 30a is argon (Ar), and the second gas 30b is helium (He). Here, the ratio of the flow rate of argon (Ar) to the flow rate of helium (He) is adjusted to be e.g. 9:1. That is, of the total flow rate of argon (Ar) and helium (He), argon (Ar) accounts for 90% of the flow rate, and helium (He) accounts for 10% of the flow rate.

In the plasma gas of the mixed gas of argon (Ar) / helium (He) subjected to electrical discharge, argon (Ar) ions and helium (He) ions are mixed. Such a plasma gas is applied toward the impurity layer 20. Thus, the impurity element included in the impurity layer 20 is injected into the semiconductor layer 10.

In the first embodiment, the impurity element to be doped to the semiconductor layer 10 is first deposited as an impurity layer 20 on the surface of the semiconductor layer 10. Then, a plasma gas of the mixed gas is applied to the impurity layer 20. Next, ions in the plasma are collided with the impurity layer 20. The impurity element included in the impurity layer 20 recoils toward the semiconductor layer 10 through the collision process in the plasma. Thus, the impurity element included in the impurity layer 20 is injected into the semiconductor layer 10.

In the first embodiment, such a method for injecting an impurity element into the semiconductor layer 10 is referred to as plasma doping of the “plasma recoil implantation type”. Furthermore, forcibly injecting the impurity element included in the impurity layer 20 into the semiconductor layer 10 by impingement from outside the impurity layer 20 is referred to as “knock-on”.

Preferable ions contributing to knock-on are ions that do not substantially affect the semiconductor characteristics, when the ions are injected into the semiconductor layer 10. Typical examples are noble gas ions and hydrogen ions described above. Furthermore, to facilitate knock-on, noble gases having a relatively large atomic mass such as argon (Ar), krypton (Kr), and xenon (Xe) are preferable. Alternatively, ions of e.g. germanium (Ge) belonging to the same group as silicon (Si) may be used instead of the noble gases.

For instance, the atomic mass of the argon ion is approximately 10 times the atomic mass of the helium ion. If an argon ion and a helium ion collide with the impurity layer 20, the argon ion having a larger atomic mass imparts a larger momentum to the impurity layer 20.

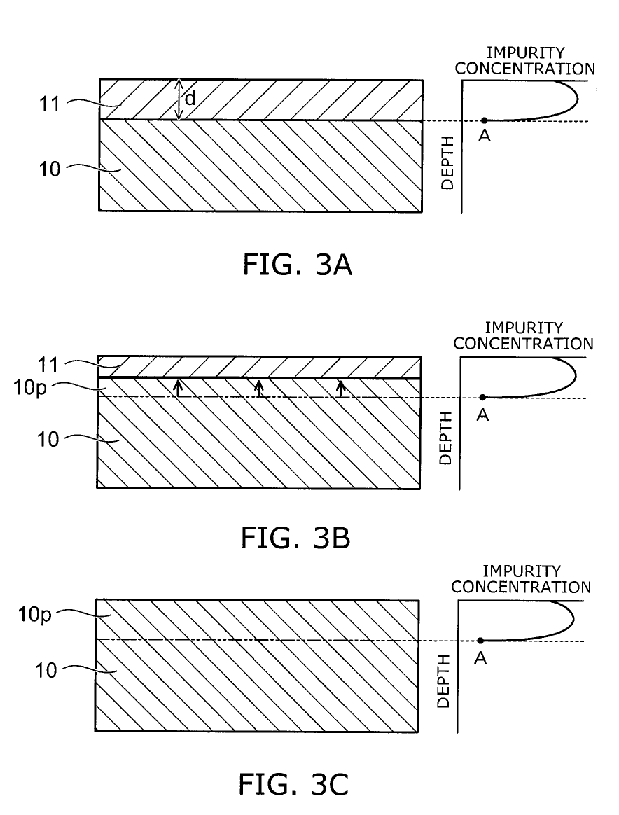

The cross section of the semiconductor layer 10 after the injection of the impurity element into the semiconductor layer 10 is shown in FIGS. 3A to 3C.

FIGS. 3A to 3C are schematic cross-sectional views for describing the process for manufacturing a semiconductor device according to the first embodiment. FIG. 3A is a schematic cross-sectional view immediately after the injection of the impurity element into the semiconductor layer. FIG. 3B is a schematic cross-sectional view of the semiconductor layer during low temperature annealing. FIG. 3C is a schematic cross-sectional view of the semiconductor layer after low temperature annealing.

The impurity concentration profile in the semiconductor layer 10 is shown on the right side of FIG. 3A. The vertical axis represents the depth from the surface of the semiconductor layer 10, and the horizontal axis represents the impurity concentration in the impurity concentration profile. The vertical axis and the horizontal axis are both scaled in arbitrary units.

In the case of using a mixed gas 30 of argon and helium, the impurity concentration profile is primarily controlled by application of argon ions having a larger atomic mass and a higher content in the mixed gas 30.

The atomic mass of helium is smaller than the atomic mass of argon. Furthermore, in the first embodiment, the content of helium is set lower than that of argon. Thus, helium ions in the mixed gas 30 do not significantly contribute to the formation of the impurity concentration profile.

However, in the plasma doping of the plasma recoil implantation type, in addition to the injection of the impurity element into the semiconductor layer 10 by knock-on with heavy ions, light ions in the plasma are penetrated into the semiconductor layer 10, modifying the surface of the semiconductor layer 10 into an amorphous layer. Here, the second noble gas atom or hydrogen is introduced more deeply into the semiconductor layer 10 than the first noble gas atom. In other words, while the first gas 30a in the plasma state is applied primarily to the impurity layer 20, the second gas 30b in the plasma state is introduced primarily into the semiconductor layer 10 through the impurity layer 20.

For instance, FIG. 3A simultaneously shows the state after the transition of the surface of the semiconductor layer 10 to an amorphous layer 11. In this stage, the impurity element included in the impurity layer 20 is entirely injected into the semiconductor layer 10 by knock-on. Hence, the impurity layer 20 is eliminated.

Furthermore, instead of completely eliminating the impurity layer 20, the method of leaving the impurity layer 20 including the impurity element on the surface of the amorphous layer 11 is also included in the embodiment. For instance, in the case where e.g. a line pattern is formed in the amorphous layer 11, the amount of plasma exposure of the sidewall of the line pattern may be relatively smaller than the amount of plasma exposure of the upper surface of the line pattern due to the masking effect. In such cases, even if the mixed gas 30 in the plasma state is applied toward the amorphous layer 11, the impurity element may remain in small amounts on the sidewall.

However, when the impurity layer 20 including the impurity element remains on the surface of the amorphous layer 11, the impurity element can be removed from the surface of the amorphous layer 11 by performing chemical treatment on the surface of the amorphous layer 11 with a mixed liquid of sulfuric acid and hydrogen peroxide. Furthermore, after the cleaning with this mixed liquid, the surface of the amorphous layer 11 may be cleaned with alkaline chemicals.

Argon ions and helium ions are simultaneously injected into the semiconductor layer 10. However, helium ions, having a smaller atomic mass, are penetrated more deeply into the semiconductor layer 10 than argon ions. That is, the amorphous layer 11 is formed thicker by using the mixed gas 30 than the amorphous layer formed by applying only argon ions to the semiconductor layer 10.

That is, in the first embodiment, the impurity concentration profile is controlled by application of ions having a relatively large atomic mass in the mixed gas 30. On the other hand, the thickness d of the amorphous layer 11 is controlled by application of ions having a relatively small atomic mass. In other words, one gas in the mixed gas 30 is used to form the impurity concentration profile, and the other gas is used to form an amorphous layer.

The shape of the impurity concentration profile, the depth d of the amorphous layer 11, or the film quality of the amorphous layer 11 is controlled by changing the combination of gases in the mixed gas 30, or changing the mixing ratio thereof.

In the first embodiment, the impurity concentration profile is controlled by application of ions having a relatively large atomic mass in the mixed gas 30. Independently, the thickness d of the amorphous layer 11 is controlled by application of ions having a relatively small atomic mass. Thus, the injection depth of the impurity element can be easily matched with the thickness d of the amorphous layer 11. Accordingly, a structure is obtained in which most of the amorphous layer 11 includes the impurity element.

Here, the injection depth of the impurity element may be defined by the so-called “junction depth”. Consider the case where a p-type semiconductor layer is formed in the surface of an n-type semiconductor layer, or conversely, an n-type semiconductor layer is formed in the surface of a p-type semiconductor layer. The “junction depth” refers to the depth of the boundary between the p-type semiconductor layer and the n-type semiconductor layer from the semiconductor surface. When the boundary between the p-type semiconductor layer and the n-type semiconductor layer is defined by the concentration of the p-type semiconductor layer, for instance, the position where the concentration of p-type impurity is 5×10¹⁸ atoms/cm³ (e.g., point A shown in FIGS. 3A to 3C) may be defined as the junction depth in the semiconductor layer.

Next, as shown in FIG. 3B, after the application of the mixed gas 30 in the plasma state, the semiconductor layer 10 is heated. For instance, low temperature annealing at 550° C. or less is performed on the semiconductor layer 10.

The amorphous layer 11 formed on the semiconductor layer 10 starts to transition to a crystal by heat treatment at approximately 400° C. By heat treatment at approximately 400° C., the amorphous layer 11 formed on the surface of the semiconductor layer 10 starts crystal growth from the interface between the amorphous layer 11 and the semiconductor layer 10, inheriting the crystal information of the semiconductor layer 10 that is the underlying monocrystal. Furthermore, the impurity element included in the amorphous layer 11 is activated during the heat treatment. Thus, a semiconductor layer 10p containing p-type impurity grows from the interface between the amorphous layer 11 and the semiconductor layer 10. The semiconductor layer 10p is a monocrystalline layer containing p-type impurity.

If the low temperature annealing is continued as it is, then as shown in FIG. 3C, the amorphous layer 11 is transformed into a monocrystalline layer by the solid phase epitaxial growth. That is, a semiconductor layer 10p containing p-type impurity is formed in the surface of the semiconductor layer 10. In this process, the impurity element injected into the amorphous layer 11 is placed into a lattice site of the monocrystalline layer. That is, while the crystallization of the amorphous layer 11 proceeds in the low temperature annealing, the impurity element is placed into a lattice site of the monocrystalline layer. Furthermore, the annealing temperature is as low as approximately 400° C. Hence, activation of the impurity element proceeds without substantial change in the impurity concentration profile. Here, when the impurity layer 20 includes n-type impurities, a monocrystalline layer containing n-type impurity is formed in the surface of the semiconductor layer 10.

In comparison with the method for manufacturing a semiconductor device according to the first embodiment, methods for manufacturing a semiconductor device according to reference examples are described below.

### REFERENCE EXAMPLE 1

In one method of plasma doping, a gas including an impurity element is directly turned into a plasma state. The semiconductor layer is exposed to this gas in the plasma state to inject the impurity element into the semiconductor layer. That is, in this method, while decomposing the gas including the impurity element above the semiconductor layer, the impurity element is injected into the semiconductor layer.

When the impurity element is injected into the semiconductor layer by plasma exposure, two phenomena primarily occur in this case.

The first phenomenon is that the ionized impurity element is accelerated by the electric field and directly injected into the semiconductor layer (direct injection). The second phenomenon is that the impurity element deposited on the semiconductor layer is subjected to impingement of the ion generated in the plasma, and is injected into the semiconductor layer by knock-on (indirect injection). The injection of the impurity element by the second phenomenon is also referred to as recoil implantation.

However, in the method of Reference example 1, the first phenomenon and the second phenomenon described above proceed simultaneously during the process. Hence, the process control is made more complex than in the first embodiment.

### REFERENCE EXAMPLE 2

In another method of plasma doping, the mixed gas 30 is not used. Only one kind of noble gas is turned into a plasma state. By knock-on with ions of this noble gas, the impurity element is injected into the semiconductor layer. In other words, the method according to Reference example 2 is a plasma recoil implantation using only one kind of noble gas.

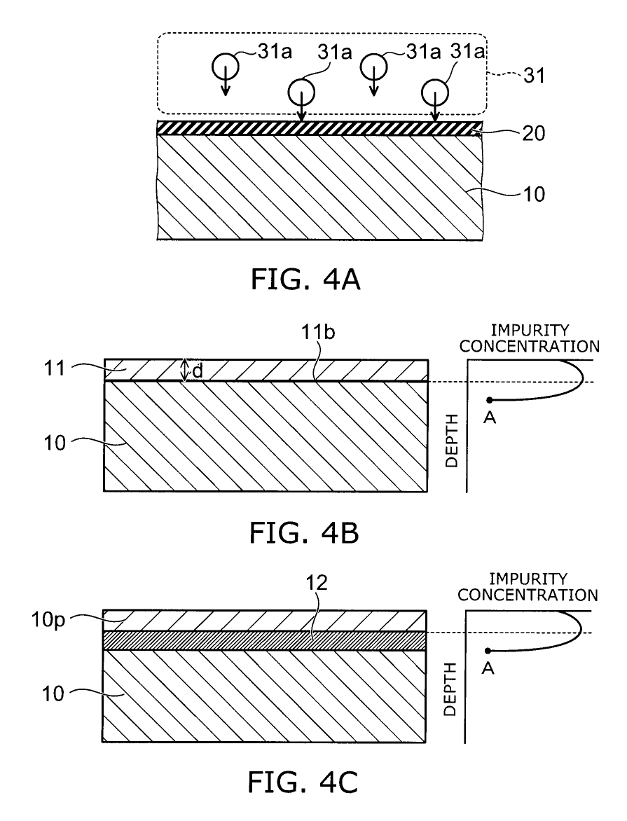

FIGS. 4A to 4C are schematic sectional views for describing a process for manufacturing a semiconductor device according to the reference example. FIG. 4A is a schematic sectional view of the semiconductor layer during plasma doping. FIG. 4B is a schematic sectional view immediately after the injection of the impurity element into the semiconductor layer. FIG. 4C is a schematic sectional view of the semiconductor layer after low temperature annealing.

As shown in FIG. 4A, in the method according to Reference example 2, as a first stage, an impurity layer 20 including an impurity element is previously formed on the semiconductor layer 10. Next, as a second stage, argon gas 31a is turned into a plasma state. Argon ions in the plasma gas 31 are applied to the impurity layer. Thus, by knock-on, the impurity element included in the impurity layer 20 is injected into the semiconductor layer 10.

FIG. 4B shows the state immediately after the injection of the impurity element into the semiconductor layer 10.

In Reference example 2, the impurity element is injected into the semiconductor layer by knock-on. Hence, the impurity concentration profile in the surface of the semiconductor layer 10 is made steeper than in Reference example 1.

In the method of Reference example 2, the plasma doping process is divided into the first stage for forming the impurity layer 20 and the second stage for knock-on. Hence, the plasma doping is made more controllable than in Reference example 1. Here, in both Reference examples 1 and 2, ions are penetrated into the semiconductor layer 10 during the progress of the process. Hence, the surface thereof is amorphized.

In Reference example 2, to increase the efficiency of knock-on, a noble gas having a larger atomic mass than argon (Ar) can be used. This is because as the atomic mass becomes larger, a larger amount of impurity element can be injected into the semiconductor layer 10 by a one ion.

However, the method according to Reference example 2 has the following problem.

In general, if ions accelerated from the plasma gas toward the semiconductor layer 10 have an equal kinetic energy, then as the atomic mass becomes larger, the ion tends to be injected less deeply into the semiconductor layer 10. That is, in the case where ions, like argon (Ar), having a larger atomic mass than helium (He) and neon (Ne) are used for knock-on, the injection depth of the impurity element may be made deeper than the bottom surface of the amorphous layer 11. For instance, FIG. 4B shows the state in which point A is located below the bottom surface 11b of the amorphous layer 11.

In an example of investigation by the inventor, boron (B) in a boron film was injected into the semiconductor layer 10 by application of argon ions. In this case, the thickness of the amorphous layer 11 was 2.6 nm (nanometers). On the other hand, the depth with the boron concentration being 5×10¹⁸ atoms/cm³ (the position of point A from the surface of the semiconductor layer 10, or the junction depth) was 4.0 nm.

That is, in Reference example 2, with the formation of the amorphous layer 11, the impurity element is injected into the semiconductor layer 10 below the amorphous layer 11. That is, in the method according to Reference example 2, it is difficult to match the injection depth of the impurity element with the thickness d of the amorphous layer 11.

In this case, when the low temperature annealing at approximately 400° C. is performed, then activation of the impurity element proceeds in the amorphous layer 11 with solid phase epitaxial growth. However, the impurity element injected into the semiconductor layer 10 below the amorphous layer 11 is difficult to activate because the annealing temperature is too low. That is, in the method according to the first embodiment, the injected impurity element is almost entirely activated. However, in the method according to Reference example 2, part of the injected impurity element is not activated.

Hence, as shown in FIG. 4C, an impurity-containing region 12 where the impurity element is not activated is formed inside the semiconductor layer 10. If the impurity element not activated remains in the semiconductor layer 10, the specific resistance of the impurity-containing region 12 may be made higher than the specific resistance of the semiconductor layer 10. Furthermore, the impurity element not activated may cause current leakage.

On the other hand, there is also considered a method for setting the annealing temperature to around 1000° C. to activate the impurity element injected into the semiconductor layer (semiconductor crystal) 10 below the amorphous layer 11. In general, immediately after the impurity element is injected into the semiconductor crystal such as silicon (Si), the impurity element is located at a position off lattice sites. Thus, by high temperature annealing at around 1000° C., the impurity element is moved to a lattice site. Accordingly, the impurity element substitutes for Si and is electrically activated. However, high temperature annealing at around 1000° C. may result in excessive diffusion of the impurity element in the semiconductor crystal, and fail to obtain the desired impurity concentration profile.

Furthermore, after ion implantation, there may be many damages (or defects) formed in the semiconductor layer 10 immediately below the amorphous layer 11, where the impurity element is injected. When the high temperature annealing treatment at around 1000° C. is performed in such a situation, enhanced diffusion is more likely to occur in the semiconductor layer 10. In the enhanced diffusion process, the impurity element is diffused faster than normal due to the effect of the damage. Hence, the injection depth of the impurity element is made even deeper. Thus, the desired impurity concentration profile is not obtained. Hence, in Reference example 2, the transistor characteristics may be degraded.

Furthermore, it may be considered to adjust the bias voltage applied to the semiconductor layer 10. However, when the injection depth of the impurity element is made shallow, the thickness of the amorphous layer 11 is simultaneously made thin. When the injection depth of the impurity element is made deep, the thickness of the amorphous layer 11 is simultaneously made thick. Hence, adjusting the bias voltage may not reduce the impurities doped beneath the amorphous layer 11 and resolve the aforementioned problem.

### REFERENCE EXAMPLE 3

One of the methods for amorphizing the surface of the semiconductor layer 10 is the PAI (pre-amorphization implantation) method. In this method, for instance, Ge ions are injected into the semiconductor layer 10 to amorphize the surface of the semiconductor layer 10 before ion-implanting the impurity element into the semiconductor layer 10. Amorphizing the surface of the semiconductor layer 10 may suppress the channeling effect in the following ion implantation.

However, the step for amorphizing the surface of the semiconductor layer 10 and the step for injecting an impurity element into the surface of the semiconductor layer 10 are separated in this method. This places a limit to the reduction of the manufacturing process.

“Channeling” is a phenomenon in which, because the traveling direction of the impurity element during ion implantation is matched with a particular orientation of the monocrystal, the impurity element travels straight in the monocrystal without being substantially scattered. Thus, the impurity element may reach a position deeper than the desired position. This is unsuitable for controlling the junction depth to a very shallow depth.

In contrast, in the first embodiment, an impurity layer 20 including an impurity element to be added to the semiconductor layer 10 is first formed on the semiconductor layer 10. Then, a mixed gas 30 in a plasma state including a first gas and a second gas is applied toward the impurity layer 20. The first gas includes a noble gas. The second gas includes another noble gas having a smaller atomic mass than the former noble gas, or hydrogen (H). At this time, ions other than desired dopant ions are injected into the semiconductor layer 10. For instance, hydrogen (H) or helium (He) used as a diluent gas is ionized and injected into the semiconductor layer 10. By injection of a large amount of these elements into the semiconductor layer, an amorphous layer 11 is formed in the surface of the semiconductor layer 10.

In the first embodiment, the impurity concentration profile is controlled by application of ions having a relatively large atomic mass in the mixed gas 30. On the other hand, the thickness d of the amorphous layer 11 is controlled by application of ions having a relatively small atomic mass.

In the first embodiment, when the amorphous layer 11 is transformed into a monocrystalline layer by solid phase epitaxial growth, the impurity element injected into the amorphous layer 11 is placed into a lattice site of the monocrystal. Because of the low annealing temperature, activation of the impurity element proceeds without substantial change in the impurity concentration profile during the process. Thus, the desired impurity concentration profile can be formed in a very shallow region from the surface of the semiconductor layer 10.

In the first embodiment, the channeling effect of ion implantation can be suppressed without using the PAI process. Furthermore, the PAI process can be omitted so that the impurity injection into the semiconductor layer 10 and the amorphization of the surface of the semiconductor layer 10 can be advanced (simultaneously) in one process. Furthermore, in the first embodiment, the formation of the impurity layer 20 and the knock-on are performed in the same vacuum processing apparatus 100. This realizes the reduction of the manufacturing process.

In the first embodiment, when the mixed gas 30 in the plasma state is applied to the impurity layer 20, parameters such as the electrical power for plasma excitation inputted to the vacuum processing apparatus 100, the frequency of the plasma excitation power, the bias potential applied to the semiconductor layer 10, the gas mixing ratio of the mixed gas 30, and the pressure of the mixed gas 30 (atmosphere pressure) are controlled.

For instance, by controlling the bias potential applied to the semiconductor layer 10, the thickness d of the amorphous layer 11 is controlled. Specifically, as the absolute value of the bias potential applied to the semiconductor layer 10 is set larger, the thickness d of the amorphous layer 11 can be made thicker.

In the mixed gas 30 in the plasma state, by increasing the proportion of the gas having a relatively small atomic mass, the amount of ions of the gas having a relatively small atomic mass can be relatively increased. For instance, as the proportion of the gas having a relatively small atomic mass is made close to 100%, the formation of the amorphous layer is favored. Thus, the junction depth can be made shallower than the bottom surface of the amorphous layer 11. Conversely, as the proportion of the gas having a relatively small atomic mass is made close to 0%, the impurity injection is favored. Thus, the junction depth can be made deeper than the bottom surface of the amorphous layer 11 (see FIG. 4B). That is, in the first embodiment, by appropriately adjusting the gas mixing ratio of the mixed gas 30, the thickness of the amorphous layer 11 before low temperature annealing is matched with the impurity injection depth.

Here, the formation of the impurity layer 20 and the knock-on may be performed in separate vacuum processing apparatuses dedicated therefor. This implementation is also included in the first embodiment.

Next, an embodiment of applying the first embodiment to manufacturing of a MOS transistor is described.

### Second Embodiment

In the second embodiment, as an example, in a process for manufacturing a planar n-channel MOS transistor, the source/drain region and the low doped extension region are formed by plasma doping of the plasma recoil implantation type.

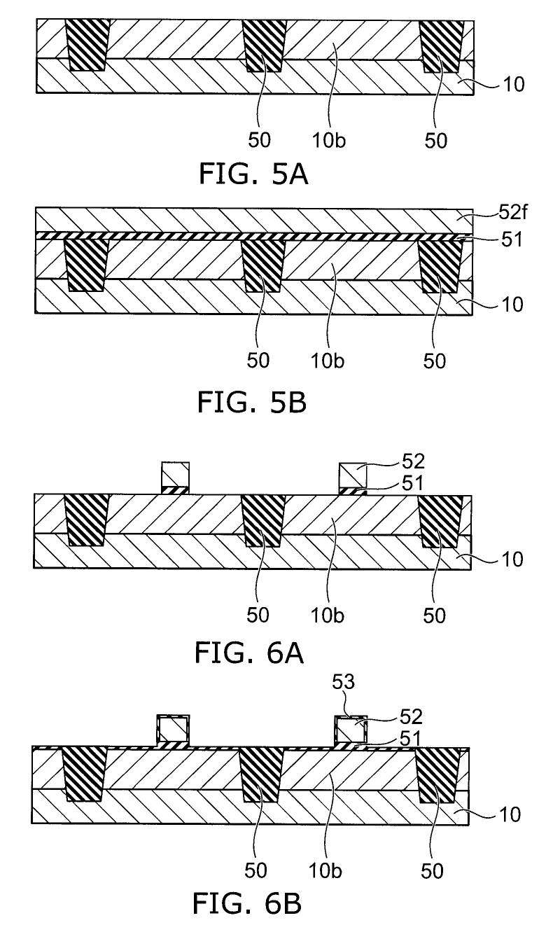

FIGS. 5A and 5B are schematic sectional views for describing a process for manufacturing a semiconductor device according to the second embodiment. FIG. 5A is a schematic cross-sectional view of a process for forming a base region and a device isolation layer in a semiconductor layer. FIG. 5B is a schematic cross-sectional view of a process for forming a gate insulating film and a polysilicon film on the semiconductor layer.

First, as shown in FIG. 5A, a semiconductor layer 10 is prepared. The semiconductor layer 10 is an n-type semiconductor substrate. Then, a p-type base region 10b is selectively formed in the surface of the semiconductor layer 10 using the ion implantation. The semiconductor layer 10 is e.g. a Si monocrystalline substrate having a (100) surface orientation. The semiconductor layer 10 is not limited to the Si monocrystalline substrate. A monocrystalline substrate of e.g. Ge, SiGe, SiC, or GaAs may be used for the semiconductor layer 10. Alternatively, an SOI (silicon on insulator) substrate may be used therefor. The p-type base region 10b may be formed by epitaxial growth on the semiconductor layer 10. Here, n-type is a first conductivity type, and p-type is a second conductivity type.

Next, to provide STI (shallow trench isolation), a device isolation layer 50 is formed in the semiconductor layer 10. For instance, a trench for a device isolation layer 50 (not shown) is formed in the semiconductor layer 10 by dry etching. Then, silicon oxide is buried in this trench to form a device isolation layer 50. The surface of the device isolation layer 50 is planarized by CMP (chemical mechanical polishing) as necessary.

Next, as shown in FIG. 5B, a gate insulating film 51 is formed on the base region 10b. Next, a polysilicon film 52f is formed on the gate insulating film 51.

The gate insulating film 51 can be e.g. a silicon oxide film formed by the thermal oxidation method or plasma oxidation method, a silicon oxynitride film formed by heat treatment or plasma treatment of a silicon oxide film in a nitrogen-containing gas, or a high dielectric (high-k) film.

After forming the polysilicon film 52f, an ion implantation process and heat treatment process are performed to adjust the threshold voltage (Vth), wherein the polysilicon film 52f becomes n-type.

FIGS. 6A and 6B are schematic sectional views for describing the process for manufacturing a semiconductor device according to the second embodiment. FIG. 6A is a schematic cross-sectional view of a process for forming a gate electrode via the gate insulating film on the base region. FIG. 6B is a schematic cross-sectional view of a process for forming a protective film on the side surface and upper surface of the gate electrode and the surface of the base region.

Next, as shown in FIG. 6A, a gate electrode 52 is selectively formed via the gate insulating film 51 on the base region 10b. For instance, by using a photolithography process, a mask pattern for forming a gate electrode is formed (not shown) on the polysilicon film 52f. Then, the polysilicon film 52f and the gate insulating film 51 are dry etched via the mask pattern. Thus, a gate electrode 52 having a prescribed pattern is formed. Between the gate electrode 52 and the base region 10b, the gate insulating film 51 remains.

Here, to reduce the resistance of the gate electrode 52, a metal material may be used instead of the polysilicon material. Furthermore, the structure of the gate electrode 52 may be a stacked structure in which a metal is stacked on the polysilicon.

Next, as shown in FIG. 6B, a protective film 53 is formed on the upper surface and side surface of the gate electrode 52, the side surface of the gate insulating film 51, and the surface of the base region 10b. The material of the protective film 53 is e.g. silicon oxide. The thickness of the protective film 53 is approximately 1 nm. The protective film 53 is formed by oxidizing the gate electrode 52 and the base region 10b.

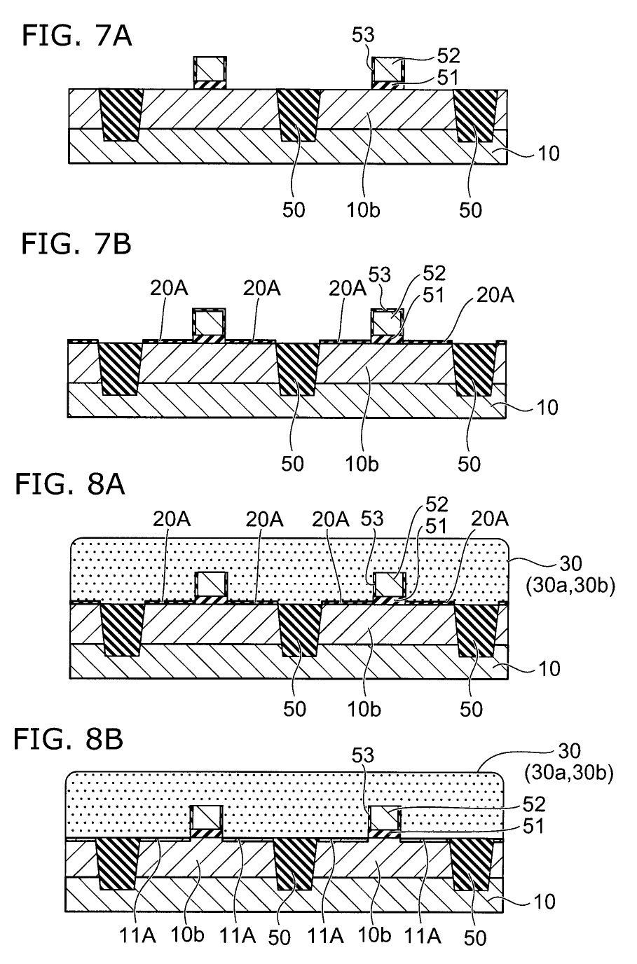

FIGS. 7A and 7B are schematic cross-sectional views for describing the process for manufacturing a semiconductor device according to the second embodiment. FIG. 7A is a schematic cross-sectional view of a process for forming a protective film on the side surface of the gate electrode. FIG. 7B is a schematic cross-sectional view of a process for forming an impurity layer including an impurity element on the base region.

Next, as shown in FIG. 7A, the protective film 53 is processed so as to expose the surface of the base region 10b. The protective film 53 is left on the side surface of the gate electrode 52. The processing of the protective film 53 is performed using selective etching. The etching may be carried out using wet etching with chemicals, or dry etching with a gas or plasma including fluorine. The thickness of the protective film 53 is as very thin as approximately 1 nm. Hence, even if the protective film 53 is left on the base region 10b, no problem occurs in performing the plasma doping described later.

Next, as shown in FIG. 7B, an impurity layer 20A (first impurity layer) including an n-type impurity element is formed on the base region 10b on both sides of the gate electrode 52. The impurity layer 20A includes e.g. phosphorus (P) or arsenic (As). The impurity layer 20A is formed by e.g. the plasma enhanced CVD method or the sputtering method.

The film thickness of the impurity layer 20A is appropriately adjusted in accordance with the target dose amount. In forming the impurity layer 20A, as described above, a bias voltage (several ten W) may be applied to the semiconductor layer 10.

To avoid contamination of the semiconductor layer 10 with oxygen, immediately before forming the impurity layer 20A, the semiconductor layer 10 may be exposed to plasma including fluorine or hydrogen in the vacuum processing apparatus 100. Thus, the oxide film formed on the surface of the semiconductor layer 10 may be removed.

FIGS. 8A and 8B are schematic cross-sectional views for describing the process for manufacturing a semiconductor device according to the second embodiment. FIG. 8A is a schematic cross-sectional view of a process for exposing the impurity layer to plasma. FIG. 8B is a schematic sectional view of a process for forming an amorphous layer on the base region.

Next, as shown in FIG. 8A, a mixed gas 30 including a first gas 30a and a second gas 30b is introduced into the vacuum processing apparatus 100. The first gas 30a includes a noble gas. The second gas 30b includes a noble gas having a smaller atomic mass than the noble gas of the first gas 30a, or hydrogen (H). Then, the first gas 30a in a plasma state including first noble gas atoms, and the second gas 30b in a plasma state including second noble gas atoms having a smaller atomic mass than the first noble gas atoms or hydrogen (H) are applied toward the impurity layer 20A.

The first gas 30a/second gas 30b is e.g. Ar/He. The flow rate ratio of Ar and He is 9:1. The atmosphere pressure is 0.5 Pa. The electrical power inputted for plasma excitation is 2000-4000 W. The electrical discharge condition is adjusted so that a bias voltage of several hundred V is applied to the semiconductor layer 10. The electrical discharge is continued until the impurity element included in the impurity layer 20A is entirely injected into the base region 10b.

Thus, as shown in FIG. 8B, an amorphous layer 11A containing n-type impurity is formed in the base region 10b.

The impurity concentration profile of the amorphous layer 11A, the thickness of the amorphous layer 11A, or the quality of the amorphous layer 11A can be adjusted by changing the combination of the mixed gas 30 to e.g. Ar/Ne, Kr/He, Kr/Ne, Kr/Ar, Xe/He, Xe/Ne, Xe/Ar, and Xe/Kr, or appropriately changing the gas mixing ratio.

The aforementioned impurity element included in the impurity layer 20A is entirely injected into the base region 10b by knock-on. Hence, the impurity layer 20A is eliminated in this stage.

The region where the amorphous layer 11A is formed was originally in the base region 10b. However, in the amorphous layer 11A, n-type impurity higher in concentration than the p-type impurity included in the base region 10b is injected. As a result, the conductivity type of the amorphous layer 11A is turned to n-type. Furthermore, the thickness of the amorphous layer 11A is made nearly equal to the injection depth of the n-type impurity.

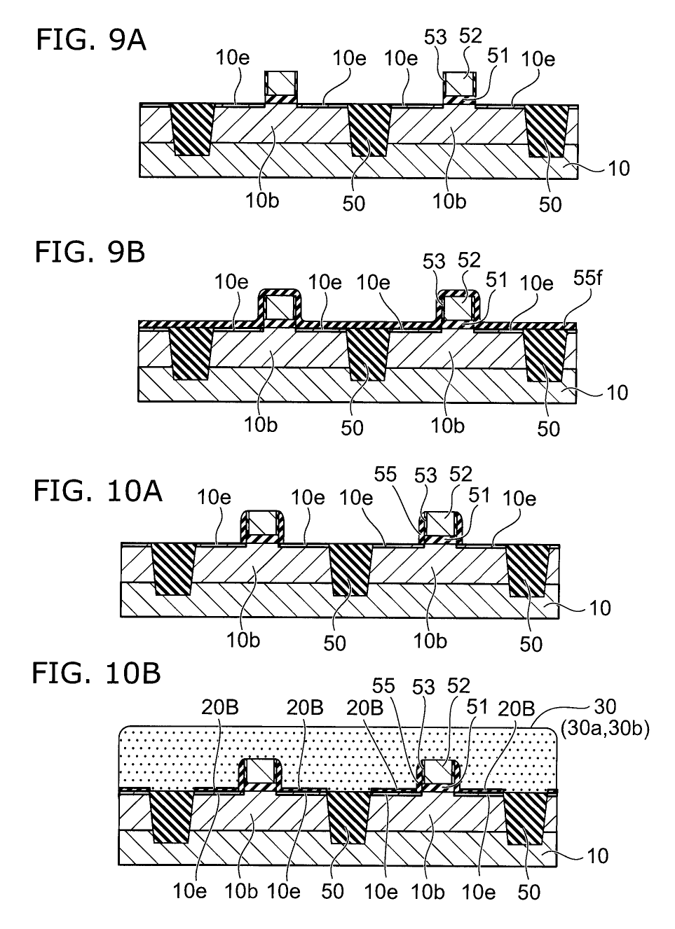

FIGS. 9A and 9B are schematic cross-sectional views for describing the process for manufacturing a semiconductor device according to the second embodiment. FIG. 9A is a schematic sectional view of a process for forming an extension region. FIG. 9B is a schematic sectional view of a process for covering the extension region and the gate electrode with an insulating film.

Next, as shown in FIG. 9A, the semiconductor layer 10 (amorphous layer 11A) is heated. Thus, an n-type extension region 10e is formed in the surface of the base region 10b on both sides of the gate electrode 52 by solid phase epitaxial growth.

For instance, heat treatment is performed at 550° C. for approximately 30 minutes using a heating furnace. Thus, the impurity element at 1×10²⁰ atoms/cm³ or more is activated in the extension region 10e. Before activation, the impurity element to be activated is entirely included in the amorphous layer 11A. Hence, activation proceeds at a high activation rate. The thickness of the extension region 10e is adjusted to be 10 nm or less.

In the second embodiment, the impurity element included in the amorphous layer 11A is activated by low temperature annealing at 550° C., forming an extension region 10e. Thus, a metal material less resistant to high temperature annealing at around 1000° C. can be adopted as the material of the gate electrode 52. This increases the degree of freedom in the choice of the material in manufacturing a semiconductor device.

In the second embodiment, instead of using a heating furnace, the semiconductor layer 10 (amorphous layer 11A) may be heated by microwave annealing. For instance, the semiconductor layer 10 (amorphous layer 11A) is heated by using a microwave of 2.45-25 GHz (gigahertz) for 30 seconds to 60 minutes, with the input power from 10 W/cm² to 10 kW/cm², and the temperature of the semiconductor layer 10 at 200-450° C.

By microwave annealing, part of the semiconductor layer 10 can be locally heated. That is, the portion of the amorphous layer 11A can be selectively heated. This further reduces heat damage to the portion other than the amorphous layer 11A. Even if the portion of the amorphous layer 11A is selectively heated by microwave annealing, activation proceeds at a high activation rate because the impurity element to be activated is entirely included in the amorphous layer 11A. Also in this case, the impurity element at 1×10²⁰ atoms/cm³ or more is activated in the extension region 10e.

In addition, the semiconductor layer 10 (amorphous layer 11A) may be heated by e.g. flash lamp annealing or laser annealing.

After forming the extension region 10e, as shown in FIG. 9B, the surface of the extension region 10e, and the side surface and upper surface of the gate electrode 52 are covered with an insulating film 55f. The insulating film 55f is formed by e.g. CVD or the sputtering method. The material of the insulating film 55f is e.g. silicon oxide (SiO₂) or silicon nitride (Si₃N₄).

FIGS. 10A and 10B are schematic cross-sectional views for describing the process for manufacturing a semiconductor device according to the second embodiment. FIG. 10A is a schematic cross-sectional view of a process for forming a sidewall protective film of the gate electrode. FIG. 10B is a schematic cross-sectional view of a process for forming an impurity layer including an impurity element on the base region.

Next, the insulating film 55f is etched back by anisotropic etching. However, the insulating film 55f is left on the sidewall of the gate electrode 52. Thus, as shown in FIG. 10A, a sidewall protective film 55 is formed on the sidewall of the gate electrode 52.

Next, as shown in FIG. 10B, an impurity layer 20B (second impurity layer) including an n-type impurity element is formed on the base region 10b on both sides of the gate electrode 52. The impurity layer 20B includes e.g. phosphorus (P) or arsenic (As). The impurity layer 20B is formed by e.g. the plasma enhanced CVD method or the sputtering method. Next, a gas in a plasma state is applied toward the impurity layer 20B. The gas includes a first gas 30a in a plasma state including first noble gas atoms, and a second gas 30b in a plasma state including second noble gas atoms having a smaller atomic mass than the first noble gas atoms or hydrogen (H).

In this stage, the thickness of the impurity layer 20B is made thicker than the thickness of the impurity layer 20A. Furthermore, the electrical discharge power in this stage is made higher than the electrical discharge power in exposing the impurity layer 20A to the plasma. Alternatively, in this stage, the absolute value of the bias potential applied to the semiconductor layer 10 is made higher. Then, the electrical discharge is continued until the impurity element included in the impurity layer 20B is entirely injected into the base region 10b. Thus, an amorphous layer having a larger thickness than the amorphous layer 11A is formed in the base region 10b.

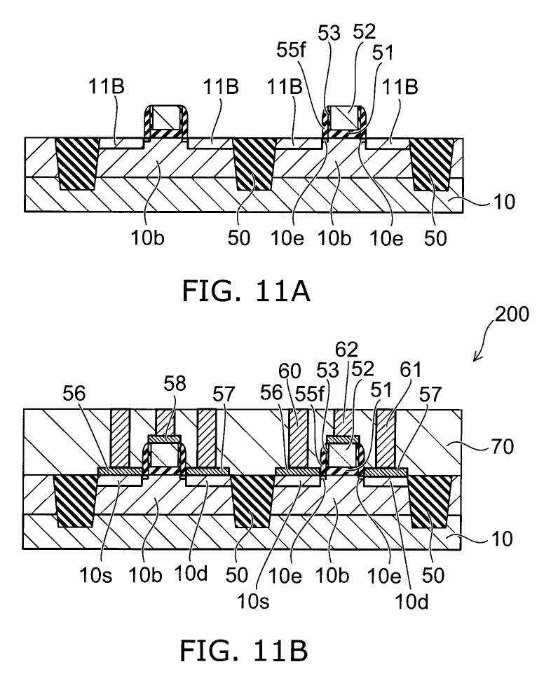

FIGS. 11A and 11B are schematic sectional views for describing the process for manufacturing a semiconductor device according to the second embodiment. FIG. 11A is a schematic cross-sectional view of a process for heating the amorphous layer. FIG. 11B is a schematic sectional view of a process for forming a source/drain region on the base region.

FIG. 11A shows the amorphous layer 11B thus formed.

The impurity concentration profile in the amorphous layer 11B, the thickness of the amorphous layer 11B, or the quality of the amorphous layer 11B can be adjusted by changing the combination of the mixed gas 30 to e.g. Ar/Ne, Kr/He, Kr/Ne, Kr/Ar, Xe/He, Xe/Ne, Xe/Ar, and Xe/Kr, or appropriately changing the gas mixing ratio. Furthermore, the impurity element included in the impurity layer 20B is entirely injected into the base region 10b by knock-on. Hence, the aforementioned impurity layer 20B is eliminated.

In this stage, n-type impurity higher in concentration than the n-type impurity included in the extension region 10e is injected into the base region 10b. Furthermore, the thickness of the amorphous layer 11B is made nearly equal to the injection depth of the n-type impurity.

Next, the semiconductor layer 10 (amorphous layer 11B) is heated. Thus, an n-type source region 10s is formed in the base region 10b on one of the two sides of the gate electrode 52 by solid phase epitaxial growth. Furthermore, a drain region 10d is formed in the surface of the base region 10b on the other of the two sides of the gate electrode 52. This state is shown in FIG. 11B.

The heat treatment is performed using one of a heating furnace, microwave annealing, flash lamp annealing, and laser annealing, as described above. The heating condition may be the same as above. The concentration of n-type impurity included in the source region 10s and the drain region 10d is adjusted to be higher than the concentration of n-type impurity included in the extension region 10e. The thickness of the source region 10s and the thickness of the drain region 10d are adjusted to be thicker than the thickness of the extension region 10e.

Also in this case, the impurity element to be activated is entirely included in the amorphous layer 11B before activation. Hence, activation proceeds at a high activation rate. Furthermore, the impurity element included in the amorphous layer 11B is activated by low temperature annealing at 550° C. This reduces heat damage to the portion other than the source region 10s and the drain region 10d.

Subsequently, as shown in FIG. 11B, silicide films 56, 57, and 58 are formed on the surface of the source/drain regions 10s and 10d, and the surface of the gate electrode 52, respectively. Next, an interlayer insulating film 70 is formed. Furthermore, contact plugs 60, 61, and 62 are connected to the silicide films 56, 57, and 58, respectively. Subsequently, a multilayer wiring process may follow. A semiconductor device 200 including a MOS transistor is formed through the foregoing manufacturing process,. Here, the formation of the source region 10s and the drain region 10d may be performed by conventional ion implantation.

Thus, in the second embodiment, by using plasma doping, the thickness of the amorphous layer is controlled to a suitable thickness without substantial change in the impurity concentration profile. In the second embodiment, by knock-on with ions in the plasma, a plasma gas including at least two kinds of noble gas elements different in atomic mass is applied to the impurity layer 20A, 20B including an impurity element.

Ions having a larger atomic mass contribute to knock-on to inject the impurity element into the semiconductor layer. Ions having a smaller atomic mass contribute to amorphization. Ions having a smaller atomic mass reach a deeper position in the semiconductor layer. Hence, the amorphous layer is formed more deeply than in the case of performing knock-on with a single gas. Furthermore, the impurity element included in the amorphous layer is activated by solid phase epitaxial growth in low temperature annealing. This further improves the productivity and reliability of LSI and other semiconductor devices.

In FIGS. 5A to 11B, the process for manufacturing an n-channel MOS transistor is shown. However, in the embodiment, naturally, the conductivity types can be interchanged so that p-type is the first conductivity type and n-type is the second conductivity type. Thus, a p-channel MOS transistor can also be formed.

Furthermore, according to the embodiment, a monocrystalline layer containing n-type impurity and a monocrystalline layer containing p-type impurity can be formed in the same semiconductor substrate. A method for this is described below.

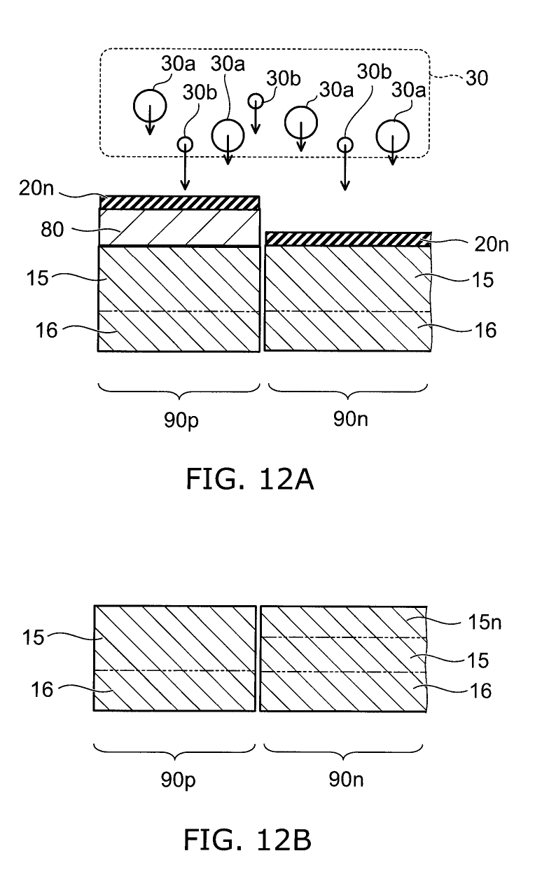

FIGS. 12A and 12B are schematic sectional views for describing a process for manufacturing a semiconductor device according to the second embodiment. FIG. 12A is a schematic cross-sectional view of a process for forming an n-type impurity layer in a semiconductor layer. FIG. 12B is a schematic cross-sectional view of the semiconductor layer after low temperature annealing.

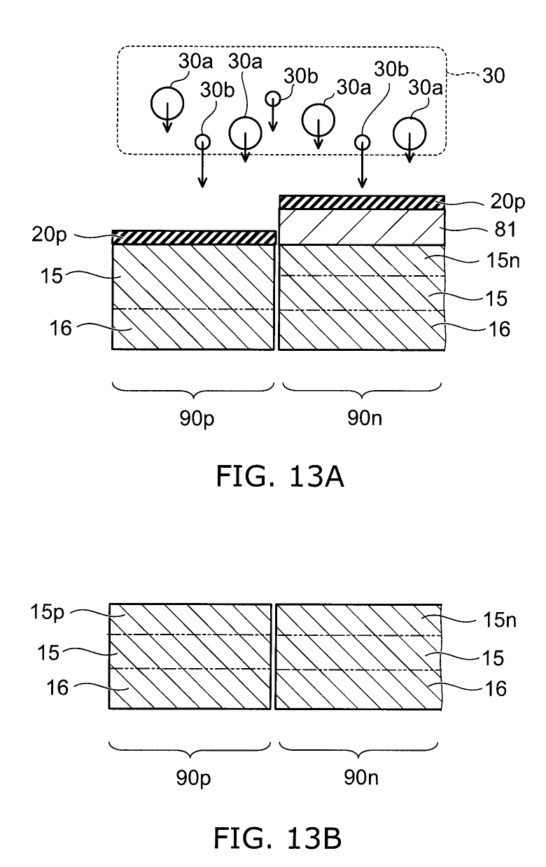

For instance, as shown in FIG. 12A, a semiconductor substrate 16 is prepared with a semiconductor layer 15 formed thereon. In FIGS. 12A to 13B, the semiconductor layer 15 and the semiconductor substrate 16 are shown as being separated horizontally. However, the semiconductor layer 15 and the semiconductor substrate 16 shown in the figures are in a one body. As described later, a monocrystalline layer containing n-type impurity is formed in the region 90n of the semiconductor substrate 16. A monocrystalline layer containing p-type impurity is formed in the region 90p.

For instance, an impurity layer 20n including an n-type impurity element (such as phosphorus (P) and arsenic (As)) is formed on the semiconductor layer 15 in the region 90n. Before forming the impurity layer 20n, a resist pattern 80 is previously formed on the semiconductor layer 15 in the region 90p. The resist pattern 80 is formed using a photolithography process. That is, the impurity layer 20n is in contact with the semiconductor layer 15 exposed from the resist pattern 80.

Next, as described above, the first gas 30a in a plasma state and the second gas 30b in a plasma state are applied toward the impurity layer 20n. Thus, the impurity element in the impurity layer 20n in contact with the semiconductor layer 15 is knocked on into the semiconductor layer 15. The impurity element in the impurity layer 20n formed on the resist pattern 80 is knocked on into the resist pattern 80, but does not reach the semiconductor layer 15.

Next, the resist pattern 80 is removed by chemical treatment or ashing treatment. Then, low temperature annealing is performed on the semiconductor layer 15. Thus, as shown in FIG. 12B, a monocrystalline layer containing n-type impurity (semiconductor layer 15n) is formed in the semiconductor layer 15 in the region 90n.

FIGS. 13A and 13B are schematic cross-sectional views for describing the process for manufacturing a semiconductor device according to the second embodiment. FIG. 13A is a schematic cross-sectional view of a process for forming a p-type impurity layer in the semiconductor layer. FIG. 13B is a schematic cross-sectional view of the semiconductor layer after low temperature annealing.

Next, as shown in FIG. 13A, an impurity layer 20p including a p-type impurity element (such as boron (B)) is formed on the surface of the semiconductor layer 15 in the region 90p. The surface of the semiconductor layer 15 in the region 90n where the impurity layer 20p is not formed is covered with a resist pattern 81. The resist pattern 81 is formed using a photolithography process. The impurity layer 20p is in contact with the semiconductor layer 15 exposed from the resist pattern 81. Then, the first gas 30a in a plasma state and the second gas 30b in a plasma state are applied toward the impurity layer 20p. Thus, the impurity element in the impurity layer 20p in contact with the semiconductor layer 15 is knocked on into the semiconductor layer 15. The impurity element in the impurity layer 20p formed on the resist pattern 81 is knocked on into the resist pattern 81, but does not reach the semiconductor layer 15.

Next, the resist pattern 81 is removed by chemical treatment or ashing treatment. Then, low temperature annealing is performed on the semiconductor layer 15. Thus, as shown in FIG. 13B, a semiconductor layer 15p containing p-type impurity is formed in the semiconductor layer 15 in the region 90p.

Here, the step for performing low temperature annealing on the semiconductor layer 15 after removing the resist pattern 80 and the step for performing low temperature annealing on the semiconductor layer 15 after removing the resist pattern 81 are divided into two steps. However, alternatively, after performing plasma doping on the semiconductor layer 15 in the region 90p and the semiconductor layer 15 in the region 90n, low temperature annealing may be collectively performed thereon.

This method can be applied to forming a CMOS (complementary metal oxide semiconductor). That is, an n-channel MOS transistor and a p-channel MOS transistor can be formed on the surface of the same semiconductor substrate 16.

For instance, the semiconductor layer 15 in the region 90n shown in FIGS. 12A and 12B can be a p-type base region. Then, by the method shown in FIGS. 12A and 12B, an n-type source/drain region and an n-type extension region can be formed in the p-type base region. Thus, an n-channel MOS transistor can be formed on the semiconductor substrate 16.

Furthermore, the semiconductor layer 15 in the region 90p shown in FIGS. 13A and 13B can be an n-type base region. Then, as shown in FIGS. 13A and 13B, a p-type source/drain region and a p-type extension region can be formed in the n-type base region. Thus, a p-channel MOS transistor can be formed on the semiconductor substrate 16.

### Third Embodiment

In the first embodiment, the first gas 30a in a plasma state and the second gas 30b in a plasma state are simultaneously applied toward the impurity layer 20 after forming an impurity layer 20. In contrast, in the third embodiment, the first gas 30a and the second gas 30b are not simultaneously applied toward the impurity layer 20.

First, as shown in FIG. 1B, an impurity layer 20 including an impurity element to be doped to the semiconductor layer 10 is formed on the semiconductor layer 10. In the first embodiment, as shown in FIG. 2B, the first gas 30a in a plasma state and the second gas 30b in a plasma state are simultaneously applied toward the impurity layer 20. In the third embodiment, one of the two steps for applying the first gas 30a in a plasma state to the impurity layer 20 and applying the second gas 30b in a plasma state to the semiconductor layer 10 is performed after forming the impurity layer 20, and then the other step is performed.

In the third embodiment, the first gas 30a in a plasma state is applied to the impurity layer 20, and then the second gas 30b in a plasma state is applied to the semiconductor layer 10. Alternatively, in the third embodiment, the second gas 30b in a plasma state is applied to the semiconductor layer 10, and then the first gas 30a in a plasma state is applied to the impurity layer 20.

Also according to this embodiment, similarly to the first embodiment, the impurity concentration profile can be controlled by applying the first gas 30a with a relatively large atomic mass in the mixed gas 30. On the other hand, the thickness d of the amorphous layer 11 can be controlled by applying the second gas 30b with a relatively small atomic mass. Hence, the injection depth of the impurity element can be easily matched with the thickness d of the amorphous layer 11.

Furthermore, when the amorphous layer 11 is transformed into a monocrystalline layer by solid phase epitaxial growth, the impurity element injected into the amorphous layer 11 can be placed into a lattice site of the monocrystal. Because of the low annealing temperature, activation of the impurity element proceeds without substantial change in the impurity concentration profile during the process. Thus, the desired impurity concentration profile can be formed in a very shallow region from the surface of the semiconductor layer 10.

The embodiments have been described above with reference to examples. However, the embodiments are not limited to these examples. More specifically, these examples can be suitably modified by those skilled in the art. Such modifications are also encompassed within the scope of the embodiments as long as they include the features of the embodiments. The components included in the above examples and their layout, material, condition, shape, size and the like are not limited to those illustrated, but can be suitably modified.

Furthermore, the components included in the above embodiments can be combined as long as technically feasible. Such combinations are also encompassed within the scope of the embodiments as long as they include the features of the embodiments. In addition, those skilled in the art can conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor device, comprising:
forming an impurity layer on a semiconductor layer, the impurity layer including an impurity element to be doped to the semiconductor layer; and
applying a first gas in a plasma state including a first noble gas atom and a second gas in a plasma state including a second noble gas atom or hydrogen (H) toward the impurity layer, the second noble gas atom having a smaller atomic mass than the first noble gas atom.

2. The method according to claim 1, wherein the second noble gas atom or the hydrogen is introduced more deeply into the semiconductor layer than the first noble gas atom.

3. The method according to claim 1, wherein the first noble gas atom is one selected from the group consisting of helium (He), neon (Ne), argon (Ar), krypton (Kr), and xenon (Xe).

4. The method according to claim 1, wherein the second noble gas atom has a smaller atomic mass than the first noble gas atom and is one selected from the group consisting of helium (He), neon (Ne), argon (Ar), and krypton (Kr).

5. The method according to claim 1, wherein combination of the first noble gas atom / the second noble gas atom is one of Ne/He, Ar/He, Ar/Ne, Kr/He, Kr/Ne, Kr/Ar, Xe/He, Xe/Ne, Xe/Ar, and Xe/Kr.

6. The method according to claim 1, wherein a negative potential relative to plasma potential of the first gas in the plasma state and the second gas in the plasma state is applied to the semiconductor layer during the first gas in the plasma state; and the second gas in the plasma state are applied to the impurity layer.

7. The method according to claim 1, wherein a mixed gas of the first gas and the second gas is excited into a plasma state.

8. The method according to claim 1, wherein the impurity element is included in an amorphous layer formed in the semiconductor layer after applying the first gas in the plasma state and the second gas in the plasma state.

9. The method according to claim 1, wherein injection depth of the impurity element into the semiconductor layer is matched with thickness of an amorphous layer formed in a surface of the semiconductor layer after applying the first gas in the plasma state and the second gas in the plasma state.

10. The method according to claim 1, wherein the semiconductor layer is heated after applying the first gas in the plasma state and the second gas in the plasma state.

11. The method according to claim 10, wherein heating temperature of the semiconductor layer is 400° C. or more and 550° C. or less.

12. The method according to claim 10, wherein an amorphous layer formed in the semiconductor layer is heated and transformed into a monocrystalline layer.

13. The method according to claim 10, wherein part of the semiconductor layer is locally heated by using microwave annealing.

14. The method according to claim 1, wherein the impurity layer is formed by using a plasma enhanced CVD method, and a bias voltage is applied to the semiconductor layer while forming the impurity layer.

15. The method according to claim 1, wherein an impurity layer including an impurity element of a first conductivity type to be doped to the semiconductor layer and an impurity layer including an impurity element of a second conductivity type are selectively formed on the semiconductor layer.

16. The method according to claim 1, wherein a resist pattern is formed on the semiconductor layer before forming the impurity layer, and the impurity layer is formed on a surface of the semiconductor layer exposed from the resist pattern.

17. The method according to claim 16, wherein the semiconductor layer is heated after removing the resist pattern.

18. A method for manufacturing a semiconductor device, comprising:
forming an impurity layer on a semiconductor layer, the impurity layer including an impurity element to be doped to the semiconductor layer; and
performing one of two steps of applying a first gas in a plasma state to the impurity layer and applying a second gas in a plasma state to the semiconductor layer, and then performing the other step, the first gas including a first noble gas atom, and the second gas including a second noble gas atom having a smaller atomic mass than the first noble gas atom or hydrogen (H).

19. A method for manufacturing a semiconductor device, comprising:
selectively forming a base region of a second conductivity type in a semiconductor layer of a first conductivity type;
selectively forming a gate electrode via a gate insulating film on the base region;
forming a first impurity layer including an impurity element of the first conductivity type on the base region on both sides of the gate electrode;
applying a first gas in a plasma state including a first noble gas atom and a second gas in a plasma state including a second noble gas atom having a smaller atomic mass than the first noble gas atom or hydrogen (H) toward the impurity layer; and
forming an extension region of the first conductivity type in a surface of the base region on both sides of the gate electrode by heating the semiconductor layer.

20. The method according to claim 19, further comprising, after forming the extension region:
forming a second impurity layer including an impurity element of the first conductivity type on the base region on both sides of the gate electrode;
applying the first gas in the plasma state and the second gas in the plasma state toward the second impurity layer; and
forming a source region in the base region on one of two sides of the gate electrode and forming a drain region in the base region on the other of the two sides of the gate electrode.
